(19) United States
(12) Patent Application Publication
(10) Pub. No.: US 2006/0198102 A1
(43) Pub. Date: Sep. 7, 2006

(54) Portable apparatus

(75) Inventor: Kyung-il Cho, Seoul (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/368,397

(22) Filed: Mar. 7, 2006

(30) Foreign Application Priority Data
Mar. 7, 2005 (KR) 2005-0018698

(51) Int. Cl. H05K 7/20

(52) U.S. Cl. 361/688

(57) ABSTRACT

A portable apparatus includes an electric device body including at least one electric part mounted therein, the electric device body having an outer circumference classified into a first region to be contacted with user's body while the portable apparatus is in use and a second region that occupies all area except the first region; and a thermal conductor installed in the electric device body so that one end thereof is connected to an electric part that generates heat while the electric device body is in operation and the other end thereof is connected to the second region, wherein the heat of the electric part is transferred out of the electric device body via the thermal conductor and the second region subsequently.

This application claims priority under 35 U.S.C. §119 from Korean Patent Application No. 2005-18698, filed on Mar. 7, 2005, the entire content of which is incorporated herein by reference.

### BACKGROUND OF THE INVENTION

1. Field of the Invention

The present invention relates to a portable apparatus, and more particularly to a portable apparatus equipped with a cooling device for cooling the portable apparatus in operation.

2. Description of the Related Art

Generally, a portable apparatus is defined as a device capable of processing radio data, audio/video data while being carried, for example, mobile phones, PMP (Portable Multimedia Player), digital cameras, PDA (Personal Digital Assistant) and laptop computers.

Recently, portable apparatuses are developed to accomplish several complicated functions to meet the demand of various users. Accordingly, more electric parts are loaded in the recent portable apparatus to cope with the recent trends. Such electric parts include an amplifier used in a tuner for receiving signals, audio/video processors for processing audio/video data, a main control unit for main control of the portable apparatus, and so on. Such electric parts mentioned above generate heat while processing complicated works rapidly, which increases internal temperature of the portable apparatus. Such increase of temperature in the portable apparatus may cause fatal damage in electric parts sensitive to temperature. In addition, portable apparatuses recently become smaller for ease of carrying. If a portable apparatus becomes smaller, the above problem may more frequently occur. In order to solve the problem, various cooling methods have been used in the prior art. However, as mentioned above, since high-performance electric parts for executing more complicated functions are mounted more and more to the portable apparatus, the conventional cooling methods do not give sufficient cooling effects on the portable apparatus. Thus, there is a need for development of a cooling device that cools a portable apparatus in an effective way.

### SUMMARY OF THE INVENTION

The present invention is designed to solve the problems of the prior art, and therefore it is an object of the invention to provide a portable apparatus provided with an improved cooling device so as to give more efficient cooling ability.

In order to accomplish the above object, the present invention provides a portable apparatus, which includes an electric device body including at least one electric part mounted therein, the electric device body having an outer circumference classified into a first region to be contacted with user's body while the portable apparatus is in use and a second region that occupies all area except the first region; and a thermal conductor installed in the electric device body so that one end thereof is connected to an electric part that generates heat while the electric device body is in operation and the other end thereof is connected to the second region, wherein the heat of the electric part is transferred out of the electric device body via the thermal conductor and the second region subsequently.

In this case, since the user's body does not frequently contact with a portion emitting heat of the portable apparatus, which emits heat outside while the portable apparatus is in use, it is possible to restrain deterioration of the cooling efficiency caused by the contact, and also to ensure that the portable apparatus may be used in an agreeable state.

According to an embodiment of the invention, the first region is made of material that is capable of intercepting heat transfer between inner and outer portions of the electric device body, and the second region includes a heat emitting unit made of material with thermal conductivity higher than that of the first region so as to transfer the heat, received from the thermal conductor, out of the electric device body.

Here, the heat emitting unit may include a plurality of heat emitting pins protruded and exposed to outside of the electric device body.

The electric device body may include at least one first casing that forms the first region and a second casing having the heat emitting unit formed on an outer circumference thereof and coupled with the first casing when the electric device body is assembled.

The electric device body includes a first body, a second body, and a hinge unit for pivotally connecting the first and second bodies, and the heat emitting unit is arranged adjacent to the hinge unit.

The second casing and the thermal conductor are integrally formed. In this case, it is possible to reduce complexity in assembling the portable apparatus due to installation of the cooling device.

### BRIEF DESCRIPTION OF THE DRAWINGS

The above aspects and features of the present invention will be more apparent by describing certain embodiments of the present invention with reference to the accompanying drawings, in which:

FIG. 1 is a perspective view showing a portable apparatus according to a first embodiment of the present invention;

FIG. 2 is a sectional view showing inner configuration of the portable apparatus, taken along the line II-II of FIG. 1;

FIG. 3 is a perspective view showing a cooling device of the portable apparatus of FIG. 1; and

FIG. 4 is a sectional view showing a portable apparatus according to a second embodiment of the present invention.

### DETAILED DESCRIPTION OF EXEMPLARY EMBODIMENTS

Hereinafter, certain embodiments of the present invention will be described in detail with reference to the accompanying drawings.

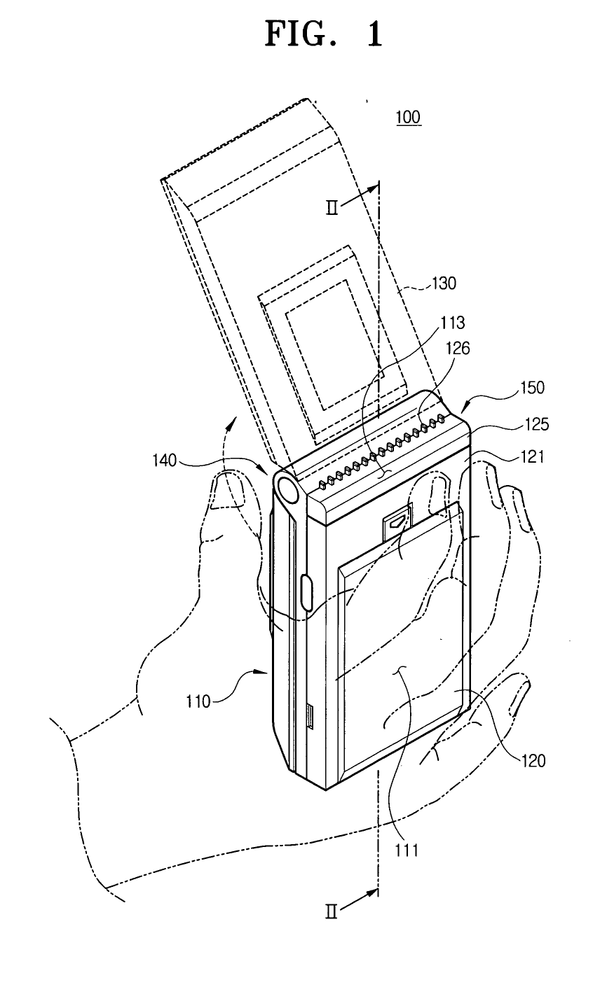

FIG. 1 shows a portable apparatus according to a first embodiment of the present invention. The portable apparatus 100 according to the first embodiment of the present invention is a mobile phone having wireless communication functions, and includes an electric device body 110 and a cooling device 150.

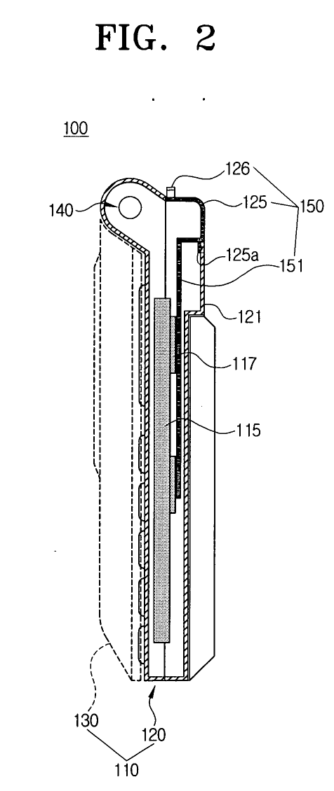

The electric device body 110 includes first and second bodies 120, 130 that are pivotally connected with each other. The first body 120 has an outline formed by a first casing 121 and a second casing 125, and various parts required for operation of the portable apparatus 100 are mounted therein. The parts include, as shown in FIG. 2, a printed circuit board 115, and electric elements 117 mounted on the printed circuit board 115 and other various electric parts, not shown. For reference, the second body 130 is prepared for expanding functions of the portable apparatus 100. In this embodiment, as shown in FIGS. 1 and 2, the second body 130 also has a function of covering and protecting a manipulation surface of the first body 120 which includes a plurality of manipulation keys, while the portable apparatus 100 is not in use.

The cooling device 150 is prepared to cool inside of the portable apparatus 100 while the portable apparatus 100 is in operation. For this purpose, the cooling device 150 of this embodiment includes a thermal conductor 151 and a second casing 125.

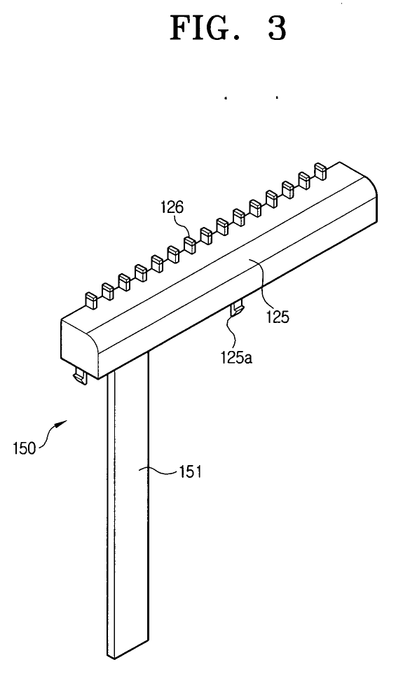

The thermal conductor 151 is made of metal material with high thermal conductivity, such as aluminum or copper. When required, auxiliary cooling material such as graphite or coolant may be further used. The thermal conductor 151 of this embodiment has one end connected to the electric element 117, such as an image processor or a central processor unit, which generates a lot of heat while the portable apparatus 100 is in operation. In case that there are a plurality of electric elements 117 to be cooled, a flat heat absorption body (not shown) may be further installed between the electric elements 117 and the thermal conductor 151 so as to absorb heat of the electric elements 117 at the same time. The second casing 125 forms a part of outer circumference of the portable apparatus 100 as mentioned above, and its one side positioned in the portable apparatus 100 is connected to the thermal conductor 151. The second casing 125 of this embodiment not only forms the outer circumference of the portable apparatus 100 but also emits heat of the electric element 117, received through the thermal conductor 151, out of the portable apparatus 100. For this purpose, the second casing 125 of this embodiment further includes a plurality of heat emitting protrusions 126 protruded out of the portable apparatus 100 as shown in FIGS. 1 and 3. In this case, a contact area between the portable apparatus 100 and the external air may be maximized, so that a cooling efficiency of the portable apparatus 100 by the second casing 125 may be improved. The second casing 125 configured as mentioned above is made of metal material with high thermal conductivity so that the internal heat of the portable apparatus 100 may be easily transferred out of the portable apparatus 100. On the contrary, the first casing 121 is made of material that may restrain transfer to the maximum of the internal heat of the portable apparatus 100 to outside. In this case, it is possible to prevent a user, who contacts with the first casing 121 of the portable apparatus 100 in operation, from feeling uncomfortable due to the heat received from the portable apparatus 100. Accordingly, the second casing 125 may be positioned in a certain region which relatively infrequently contacts with user's body while the portable apparatus 100 is in use, thereby preventing deterioration of the cooling efficiency through the second casing 125 caused by contact between the second casing 125 and the user and also preventing discomfort of the user as mentioned above. That is to say, in case of a common portable apparatus 100, as shown in FIG. 1, it may be classified into a first region 111 that is gripped by a user while the portable apparatus 100 is in operation and a second region 113 only infrequently contacted with the user. In order to give the above function, the second casing 125 should be positioned in the second region 113. In this embodiment, the second casing 125 is arranged adjacent to a hinge unit 140 that connects the first body 120 and the second body 130. Meanwhile, as shown in FIG. 3, the second casing 125 of this embodiment is integrally formed with the thermal conductor 151. Of course, it causes no problem in attaining the effects of the present invention if the second casing 125 is separately installed from the thermal conductor 151. However, if the second casing 125 is integrally formed with the thermal conductor 151 as in this embodiment, the thermal conductor 151 may be assembled together with the second casing 125, so it is possible to simplify the assembling process of the portable apparatus 100. Reference numeral 125a denotes a coupling protrusion used for coupling between the second casing 125 and the first casing 121.

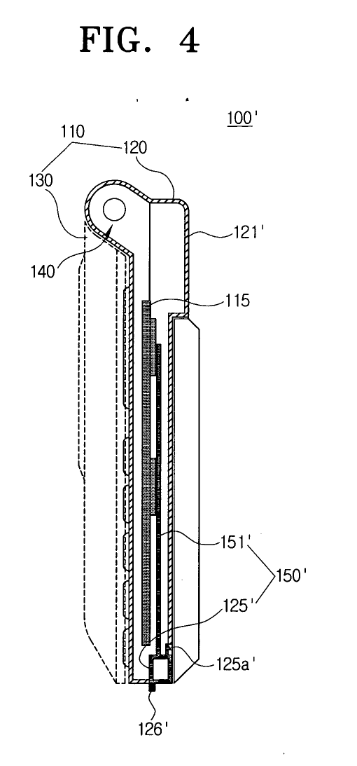

FIG. 4 shows a portable apparatus according to a second embodiment of the present invention. Referring to FIG. 4, the portable apparatus 100′ of this embodiment is configured so that the second casing 125′ is arranged to a lower end of the portable apparatus 100′. The lower end of the portable apparatus 100′ is also pertained to the second region 113 (see FIG. 1) that contacts with user's body relatively infrequently in comparison to the first region 111 (see FIG. 1). The second casing 125′ may give the same effects as the former embodiment though it is arranged to the lower end of the portable apparatus 100′. Meanwhile, the portable apparatus 100′ of this embodiment is substantially identical to that of the former embodiment except that a thermal conductor 151′ is configured to connect the electric element 117 and the portable apparatus 100′, so it is not described in detail here.

Heretofore, a mobile phone is selected as an example to describe the present invention. However, the present invention may also be applied to various portable apparatuses, such as PMP, PDA, camcorder, and digital camera in addition to mobile phone.

According to the present invention described above, a part of the outer circumference of the portable apparatus, which only infrequently contacts with user's body while the portable apparatus is in use, is used for cooling the portable apparatus. Since the portion emitting heat of the portable apparatus does not contact with the user, it is possible to restrain deterioration of the cooling efficiency caused by the contact and also to ensure that the portable apparatus may be used in an agreeable state.

In addition, since the second casing is integrally formed with the thermal conductor, an improved cooling efficiency may be provided through the simple assembling process as mentioned above.

Though the exemplary embodiments have been depicted and explained to illustrate the principle of the present invention, the present invention is not limited to the depicted and explained configuration and operation themselves. Instead, it should be understood that those skilled in the art might change or modify the present invention within the scope and spirit defined in the appended claims. Therefore, all of appropriate changes and modifications should be considered to be included in the scope of the invention.

What is claimed is:

1. A portable apparatus, comprising:
an electric device body including at least one electric part mounted therein, the electric device body having an outer circumference classified into a first region to be contacted with user's body while the portable apparatus is in use and a second region that occupies all area except the first region; and
a thermal conductor installed in the electric device body so that one end thereof is connected to an electric part that generates heat while the electric device body is in operation and the other end thereof is connected to the second region,
wherein the heat of the electric part is transferred out of the electric device body via the thermal conductor and the second region subsequently.

2. The portable apparatus according to claim 1, wherein
the first region is made of material that is capable of intercepting heat transfer between inner and outer portions of the electric device body, and
the second region includes a heat emitting unit made of material with thermal conductivity higher than that of the first region so as to transfer the heat, received from the thermal conductor, out of the electric device body.

3. The portable apparatus according to claim 2, wherein the electric device body includes at least one first casing that forms the first region and a second casing having the heat emitting unit formed on an outer circumference thereof and coupled with the first casing when the electric device body is assembled.

4. The portable apparatus according to claim 3, wherein the heat emitting unit includes a plurality of heat emitting pins protruded and exposed to outside of the electric device body.

5. The portable apparatus according to claim 3, wherein
the electric device body includes a first body, a second body, and a hinge unit for pivotally connecting the first and second bodies, and
the heat emitting unit is arranged adjacent to the hinge unit.

6. The portable apparatus according to claim 3, wherein the second casing and the thermal conductor are integrally formed.

7. The portable apparatus according to claim 2, wherein the heat emitting unit includes a plurality of heat emitting pins protruded and exposed to outside of the electric device body.

8. The portable apparatus according to claim 2, wherein
the electric device body includes a first body, a second body, and a hinge unit for pivotally connecting the first and second bodies, and
the heat emitting unit is arranged adjacent to the hinge unit.
